(19) United States
(12) Patent Application Publication
(10) Pub. No.: US 2026/0029224 A1
(43) Pub. Date: Jan. 29, 2026

(54) SENSOR OPTIMIZATION TO IDENTIFY LOCATION AND ORIENTATION OF ANISOTROPIC MAGNET FIELD FROM A PERMANENT MAGNET

(71) Applicant: Stryker Corporation, Portage, MI (US)

(72) Inventors: Ananth RAVI, Toronto (CA); John DILLON, Mississauga (CA); Mark SEMPLE, Toronto (CA); Prashant PANDEY, Toronto (CA); Michael GIANNINI, Toronto (CA)

(73) Assignee: Stryker Corporation, Portage, MI (US)

(21) Appl. No.: 19/105,261

(22) PCT Filed: Aug. 23, 2023
(86) PCT No.: PCT/IB2023/000518

§ 371 Date: Feb. 20, 2025

Related U.S. Application Data
(60) Provisional application No. 63/400,399, filed on Aug. 23, 2022.

(51) Int. Cl. G01B 7/004; G01B 7/30; G01R 33/00; G01R 33/02

(52) U.S. Cl. CPC G01B 7/004; G01B 7/30; G01R 33/0094; G01R 33/0206

(57) ABSTRACT

The present disclosure may be embodied as a probe for determining a position and pose of an anisotropic magnetic marker having a known size, shape, and magnetization. The probe has a substrate having a first side, a second side, a longitudinal axis, and a transverse axis. A first magnetic sensor is on the first side of the substrate. A second magnetic sensor is on the first side of the substrate and spaced apart from the first magnetic sensor along the longitudinal axis of the substrate and spaced apart from the first magnetic sensor along the transverse axis of the substrate. A third magnetic sensor is on the second side of the substrate. Each of the first magnetic sensor, the second magnetic sensor, and the third magnetic sensor is a multidimensional magnetic sensor. A processor is configured to determine a disposition of the magnetic marker in five degrees of freedom.

### CROSS-REFERENCE TO RELATED APPLICATIONS

This application is a U.S. national stage application under 35 U.S.C. § 371 of International Application No. PCT/IB2023/000518, filed Aug. 23, 2023, which claims the priority of U.S. Application No. 63/400,399, filed Aug. 23, 2022. The entire contents of each priority application is incorporated herein by reference.

### FIELD OF THE DISCLOSURE

The present disclosure relates to localization of markers, and in particular, determining a location and pose of a magnetic marker.

### BACKGROUND OF THE DISCLOSURE

Surgery and other medical procedures/therapies often require accurate localization of an area of interest. Despite advances in modalities and sensors, typical localization techniques involve the use of large sensor probes to accurately localize a wire, seed, or marker. Thus, there is a need for probes which use optimized sensor position so as to decrease a size of the probe, while at the same time allowing for localization of magnetic marker in five degrees of freedom.

### BRIEF SUMMARY OF THE DISCLOSURE

The present disclosure may be embodied as a probe for determining a position and pose of an anisotropic magnetic marker having a known size, shape, and magnetization. The probe has a substrate having a first side, a second side, a longitudinal axis, and a transverse axis. In some embodiments, the substrate has a thickness of between 0.5 mm and 10 mm. A first magnetic sensor is disposed on the first side of the substrate. A second magnetic sensor is disposed on the first side of the substrate and spaced apart from the first magnetic sensor along the longitudinal axis of the substrate and spaced apart from the first magnetic sensor along the transverse axis of the substrate.

A third magnetic sensor is disposed on the second side of the substrate. Each of the first magnetic sensor, the second magnetic sensor, and the third magnetic sensor is a multidimensional magnetic sensor. The third magnetic sensor may be spaced apart from the first magnetic sensor along the longitudinal axis. The third magnetic sensor may be spaced apart from the first magnetic sensor along the transverse axis. The third magnetic sensor may be spaced apart from the first magnetic sensor along the longitudinal axis and the transverse axis. The third magnetic sensor may be spaced apart from the second magnetic sensor along the longitudinal axis. The third magnetic sensor may be spaced apart from the second magnetic sensor along the transverse axis. The third magnetic sensor may be spaced apart from the second magnetic sensor along the longitudinal axis and the transverse axis.

A processor is in electronic communication with the first magnetic sensor, the second magnetic sensor, and the third magnetic sensor. The processor is configured to (e.g., programmed to) determine a disposition of the magnetic marker in five degrees of freedom based on the known size, shape, and magnetization (of the magnetic marker) and signals received from each of the first, second, and third magnetic sensors.

In some embodiments, the spacing between the first and second magnetic sensors is greater along the longitudinal axis than the spacing between the first and second magnetic sensors along the transverse axis.

In some embodiments, at least one of the first magnetic sensor, the second magnetic sensor, and the third magnetic sensor is oriented such that no measurement axis (of such magnetic sensor(s)) is parallel with the longitudinal axis of the substrate. In some embodiments, at least one of the first magnetic sensor, the second magnetic sensor, and the third magnetic sensor has a different orientation from the other magnetic sensors.

In some embodiments, the probe may have a fourth magnetic sensor. The fourth magnetic sensor may be disposed on the first side of the substrate. The fourth magnetic sensor may be disposed on the second side of the substrate. The fourth magnetic sensor may be spaced apart from the third magnetic sensor along the longitudinal axis. The fourth magnetic sensor may be spaced apart from the third magnetic sensor along the transverse axis. The fourth magnetic sensor may be spaced apart from the third magnetic sensor along the longitudinal axis and the transverse axis.

In some embodiments, a maximum total spacing between the first magnetic sensor, the second magnetic sensor, and the third magnetic sensor along the transverse axis is less than or equal to 12 mm. In some embodiments, a maximum total spacing between the first magnetic sensor, the second magnetic sensor, and the third magnetic sensor along the transverse axis is 12 mm, and along the longitudinal axis is between 1.25 and 10 times the maximum total spacing along the longitudinal axis.

The probe may further include a user interface in electronic communication with the processor. The processor may be further configured to provide a signal of the determined disposition of the magnetic marker to the user interface. The user interface may be a monitor configured to display the determined disposition of the magnetic marker according to the signal provided from the processor. The user interface may be an audio source configured to audibly represent the determined disposition of the magnetic marker according to the signal provided from the processor.

The processor may have a first mode in which the disposition of the magnetic marker is determined in five degrees of freedom and a second mode wherein the disposition of the magnetic marker is determined using one of the first magnetic sensor, the second magnetic sensor, or the third magnetic sensor.

The processor may be configured to determine more than one disposition of the magnetic marker over time. The processor may be configured to periodically determine the disposition of the magnetic marker at a sampling frequency.

In some embodiments, the substrate is contained within a probe housing. The magnetic sensors (i.e., first magnetic sensor, second magnetic sensor, etc.) may be contained within the probe housing. The processor may be located outside the probe housing.

The processor may be further configured to provide an indicator signal when magnetic field gradients which are not consistent with the magnetic marker are detected. The processor may be further configured to disregard magnetic field gradients which are not consistent with the magnetic marker.

In some embodiments, one of the first magnetic sensor, the second magnetic sensor, or the third magnetic sensor is spaced apart from the other magnetic sensors along the longitudinal axis and configured to measure a background magnetic field.

In some embodiments, the probe has a background magnetic sensor spaced apart from the first magnetic sensor, the second magnetic sensor, and the third magnetic sensor, along the longitudinal axis, and configured to measure a background magnetic field.

### BRIEF DESCRIPTION OF THE DRAWINGS

For a fuller understanding of the nature and objects of the disclosure, reference should be made to the following detailed description taken in conjunction with the accompanying drawings.

FIG. 1 is a diagram showing an embodiment of a probe according to an embodiment of the present disclosure.

FIG. 2 is a diagram showing another embodiment of a probe according to an embodiment of the present disclosure.

FIG. 3 is a diagram showing another embodiment of a probe according to an embodiment of the present disclosure.

FIG. 4 is a diagram showing another embodiment of a probe according to an embodiment of the present disclosure.

FIG. 5 is a diagram showing another embodiment of a probe according to an embodiment of the present disclosure.

FIG. 6 is a diagram showing another embodiment of a probe according to an embodiment of the present disclosure.

FIG. 7 is a diagram showing another embodiment of a probe according to an embodiment of the present disclosure.

### DETAILED DESCRIPTION OF THE DISCLOSURE

Embodiments of the present disclosure may provide a real-time 3D magnet positional information system that accounts for magnet anisotropy of the magnet. A magnet's field strength may be modeled at any position if the location, orientation, size, shape, and magnetization of the magnet is known. However, the reverse does not apply. In other words, given a magnetic field sample, there is no direct equation for calculating the location of the source magnet, even if its size, shape, and magnetization are known. The present disclosure provides embodiments of a probe designed to locate a hidden magnet source (magnetic marker) using measurements from a discrete magnetic sensor array. By design, the target magnet's size, shape, and magnetization are known, and the remaining parameters (location and orientation/anisotropy) can be estimated using a variety of numerical methods. In some embodiments, this disclosure provides a probe with sensor arrays designed such that:
1. They are sufficiently spaced to provide enough information to resolve the SD coordinates of the marker.
2. The sensor arrangement is constrained to a 1 cm outer diameter, this is driven by most surgical applications requiring smaller incisions, which necessitates probes to be able to fit in tiny cavities. Additionally, it will also help with laparoscopic procedures, where the trocars used to introduce instruments are on the order of 1 cm in diameter.
3. Provide sufficient information in order to be able to handle two or more markers in the space.

A typical method to determine the solution for such a linear systems of equations is using a gradient descent algorithm such as the one described below. Here r_{i,j} represents the position in cartesian coordinates as well as the angular pose of the marker i in terms of pitch and yaw, with respect to the magnetometer j. M refers to the set of magnetometer measurements, where M(x, y, z) represents a collection of magnetic field measurements at a particular point. B_{i,j}(r) is the calculated magnetic field based on the magnetic dipole moment (m) of marker i with respect to the position of magnetometer j. μ₀ is the magnetic permeability of free space (a constant).

$${r}_{i , j} = [ x , y , x , θ , φ ] \qquad ( 1 )$$

$${M}_{j} ( x , y , z ) = {\sum }_{i = 1}^{\# of markers} {B}_{i , j} ( {r}_{i , j} ) \qquad ( 2 )$$

$$[ \begin{matrix}{M}_{1} \\ ⋮ \\ {M}_{n}\end{matrix} ] = [ \begin{matrix}\frac{{μ}_{0}}{4 π} ( \frac{3 {\hat{r}}_{1 , 1} ( {\hat{r}}_{1 , 1} \cdot m ) - m}{{\vert {r}_{1 , 1} \vert}^{3}} ) \\ ⋮ \\ \frac{{μ}_{0}}{4 π} ( \frac{3 {\hat{r}}_{1 , n} ( {\hat{r}}_{1 , n} \cdot m ) - m}{{\vert {r}_{1 , n} \vert}^{3}} )\end{matrix} ] \qquad ( 3 )$$

$$M - B ( r ) = 0 \qquad ( 4 )$$

One example of determining r, would be to minimize the following cost/loss function F(r). Where F(r)will tend towards 0, when the exact position and pose of the marker is determined.)

$$F ( r ) = {‖ M - B ( r ) ‖}^{2} \qquad ( 5 )$$

$${min}_{r ∈ ℝ} F ( r ) \to 0 \qquad ( 6 )$$

If the loss/cost function does not converge towards a minima, this is indicative of a noisy environment and can be used as a flag to warn users of potential sources a spurious magnetic signals.

The problem may be set up with more degrees of constraint than degrees of freedom to avoid singularities. Each additional marker pose adds five degrees of freedom to the search problem, and each additional sensor offers three degrees of constraint.

Minimizing the above cost function can be achieved using the gradient descent algorithm. This algorithm iteratively evaluates the cost function and changes the search parameters in the direction of greatest negative gradient. The algorithm stops when the gradient reaches a value close to zero.

The above provides an illustrative technique for determining position and pose of the marker(s). This example is intended be non-limiting, and other techniques may be used and are within the scope of the present disclosure.

### Sensor Layout

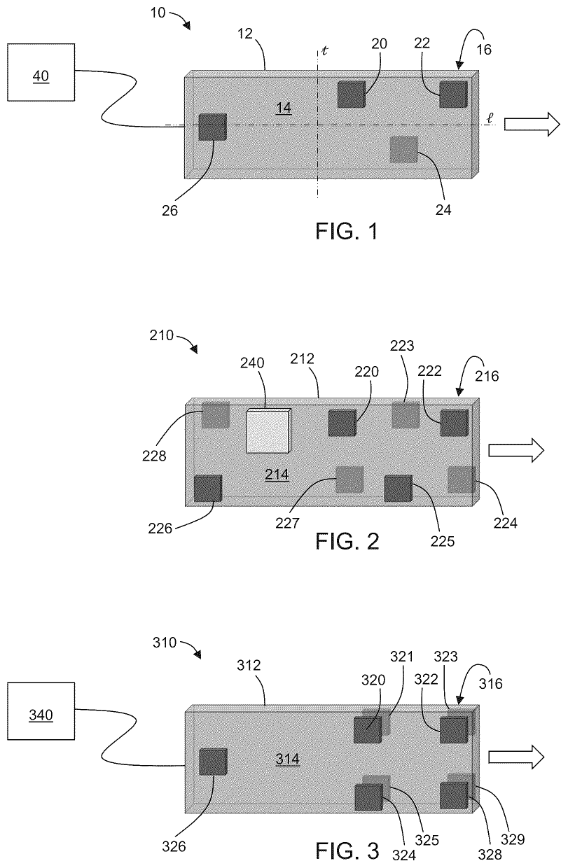

The sensor array geometry (locations and spacings) feeds into the system's localization accuracy. Array configurations with 3-D sensor distributions (i.e., non-coplanar arrangements) are provided to reduce ambiguities and singularities around the detector probe. A minimum number of sensors is required to determine/track the magnet's 3D position and pose. In general, more sensors are better than fewer sensors, but with diminishing accuracy improvements. The algorithms can all be scaled to the number of sensors, at the cost of the added computational burden. Some configurations that have been explored have between 3 and 16 sensors, in various arrangements defining a 3D array. Exemplary embodiments are illustrated in FIGS. 1-6 and further described below. The sensor spacing is constrained to maintain a probe diameter of less than 12 mm, and preferably 10 mm in diameter as a maximum outer dimension. Minimizing the dimension enables use for minimally-invasive surgeries require which utilize small incisions. These incisions are on the order of 10 mm. The challenge is creating a probe system that provides sufficient information to accurately localize markers within such a small form factor.

With reference to FIG. 1, the present disclosure may be embodied as a probe 10 for determining a position of an anisotropic magnetic marker. The magnetic marker has a size, shape, and magnetization that is known—e.g., pre-determined, measured, otherwise obtained, etc. The probe 10 has a substrate 12 with a first side 14 and a second side 16. The substrate 12 has a longitudinal axis l and a transverse axis [symbol] perpendicular to the longitudinal axis (such that the longitudinal and transverse axes are on a plane parallel to the first side 14 and/or the second side 16). In some embodiments, the substrate has a thickness of between 0.5 mm and 10 mm, inclusive. In some embodiments, the substrate has a thickness of between 0.8 mm and 1.2 mm, inclusive, such as, for example, 1.0 mm. The probe includes a first magnetic sensor 26 disposed on the first side 14 of the substrate 12. The first magnetic sensor may be a multidimensional magnetic sensor having measurement axes in more than one dimension, such as, for example, a 3-dimensional (3D) magnetic sensor having three orthogonal measurement axes.

A second magnetic sensor 20 is disposed on the first side 14 of the substrate 12 and spaced apart from the first magnetic sensor 26 along the longitudinal axis and the transverse axis. The second magnetic sensor 20 may be a multidimensional magnetic sensor having measurement axes in more than one dimension, such as, for example, a 3D magnetic sensor. In some embodiments, the spacing between the first magnetic sensor and the second magnetic sensor is greater along the longitudinal axis than the spacing between the first magnetic sensor and the second magnetic sensor along the transverse axis.

A third magnetic sensor 24 is disposed on the second side 16 of the substrate 12. The third magnetic sensor 24 may be spaced apart from the first magnetic sensor 26 along the longitudinal axis and/or the transverse axis. The third magnetic sensor 24 may be spaced apart from the second magnetic sensor 20 along the longitudinal axis and/or the transverse axis. The second magnetic sensor 20 may be a multidimensional magnetic sensor having measurement axes in more than one dimension, such as, for example, a 3D magnetic sensor. The third magnetic sensor may be spaced apart from the first magnetic sensor along the longitudinal axis. The third magnetic sensor may be spaced apart from the first magnetic sensor along the transverse axis. The third magnetic sensor may be spaced apart from the second magnetic sensor along the longitudinal axis. The third magnetic sensor may be spaced apart from the second magnetic sensor along the transverse axis.

In some embodiments, at least one of the first magnetic sensor, the second magnetic sensor, and the third magnetic sensor is oriented such that no measurement axis is parallel with the longitudinal axis of the substrate. For example, the first magnetic sensor may be rotated on the first side of the substrate such that the measurement axes are not parallel to either of the longitudinal axis and the transverse axis. Where more than one of the magnetic sensors are oriented in this manner, they may be similarly oriented (e.g., such that the corresponding measurement axes of such magnetic sensors are parallel to each other) or they may be differently oriented (e.g., such that the corresponding measurement axes of such magnetic sensors are not parallel to each other).

In some embodiments, a maximum total spacing between the first magnetic sensor, the second magnetic sensor, and the third magnetic sensor along the transverse axis is less than or equal to 12 mm. In some embodiments, the spacing between the outermost magnetic sensors (including the first magnetic sensor, the second magnetic sensor, the third magnetic sensor, and any additional magnetic sensors (further described below)) is less than or equal to 12 mm. For example, in some embodiments, the total spacing between the first magnetic sensor, the second magnetic sensor, and the third magnetic sensor along the transverse axis does not exceed 10 mm. In some embodiments, the maximum total spacing between the first magnetic sensor, the second magnetic sensor, and the third magnetic sensor (and additional magnetic sensors, if any) along the longitudinal axis is between 1.25 and 10 times the maximum total spacing along the longitudinal axis.

The probe may have one or more additional magnetic sensors on either of the first side or the second side of the substrate (or both where more than one additional magnetic sensors are presented). For example, probe 10 of FIG. I includes a fourth magnetic sensor 22 disposed on the first side 14 of the substrate 12. One or more of the additional magnetic sensors, if any, may be multidimensional magnetic sensors, such as, for example, 3D magnetic sensors. The additional magnetic sensor(s) may be spaced apart from one or more of the first magnetic sensor, the second magnetic sensor, and the third magnetic sensor along the longitudinal axis and/or the transverse axis. For example, fourth magnetic sensor 22 of FIG. I is spaced apart from the first magnetic sensor 26 along both of the longitudinal axis and the transverse axis, spaced apart from the second magnetic sensor 20 along the longitudinal axis, and spaced apart from the third magnetic sensor 24 along both of the longitudinal axis and the transverse axis.

The probe may have a background magnetic sensor spaced apart from the first magnetic sensor, the second magnetic sensor, the third magnetic sensor, and any additional magnetic sensors. The background magnetic sensor is spaced apart from the other magnetic sensors along (at least) the longitudinal axis. The background magnetic sensor is configured to measure (i.e., detect) a background magnetic field—for example, measure only the background (ambient) magnetic field. For example, the background magnetic sensor may be located such that when a field of a magnetic marker is detectable by the first, second, and/or third magnetic sensors, such marker field is not detectable by the background magnetic sensor (i.e., the field detected by the background magnetic sensor is de minimis). In this way, the background magnetic field may be removed from the field detected by the first, second, and third magnetic sensors (and additional magnetic sensors, if any)—i.e., background rejection. Such background fields may result from the earth's magnetic field, stray magnetic fields from nearby materials and devices, etc. The background magnetic sensor may be at a location more distal from the tip of the probe than the other sensors. In this way, the background magnetic sensor is at a location far enough away from the probe tip so as to not detect a marker's field when the tip of the probe is near the marker. The processor may be configured to remove the field detected by the background magnetic sensor. For example, the processor may subtract the field detected by the background magnetic sensor from the field(s) detect by the other magnetic sensors. In some embodiments, one of the first magnetic sensor, the second magnetic sensor, or the third magnetic sensor is spaced apart from the other magnetic sensors and configured as a background magnetic sensor (i.e., configured to measure a background magnetic field).

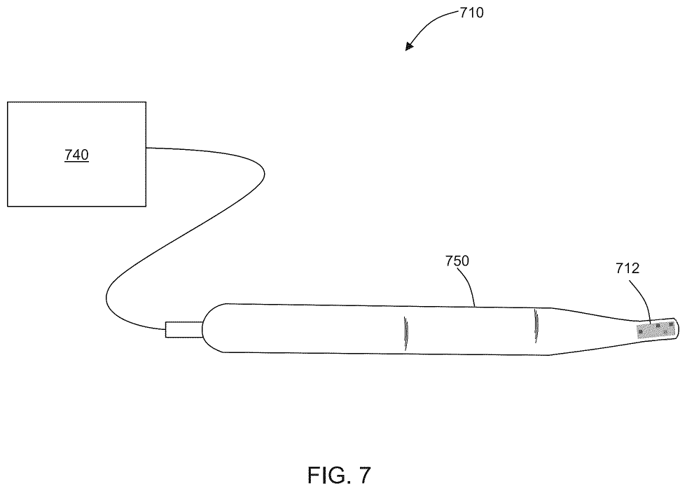

The probe 10 includes a processor 40 in electronic communication with each magnetic sensor (e.g., first magnetic sensor, second magnetic sensor, and third magnetic sensor). The processor may be contained within a housing of a probe. For example, the processor may be disposed on the substrate which is contained within a housing of the probe. In other embodiments, the processor is located outside of the housing of the probe. For example, the processor may be remotely located and in communication with the sensors via wired or wireless connection. FIG. 1 depicts a processor 40 which is located outside of a housing (not shown) of the probe. FIG. 7 shows an example of a probe 710 having a processor 740 located outside of a housing 750. Substrate 712 is shown contained within the housing 750.

The processor is configured to determine a disposition of a magnetic marker in at least five degrees of freedom (5 DoF). The disposition of the magnetic marker is determined based on its known size, shape, and magnetization, as well as signals received by the processor from each of the first magnetic sensor, the second magnetic sensor, and the third magnetic sensor (and additional magnetic sensors of the probe, if any). The processor may be further configured to disregard magnetic field gradients which are not consistent with the magnetic field gradients of the magnetic marker (i.e., the a prior known magnetic field of the magnetic marker). The processor may be configured to determine more than one disposition of the magnetic marker over time. For example, the processor may be configured to periodically determine the disposition of the magnetic marker at a sampling frequency.

In some embodiments, the processor may be configured to have multiple operating modes. Magnetic field strength falls off dramatically with distance. Farther away from a magnet, the signals are much weaker, and the system's estimations will be littered with noise. This is a result of a low signal-to-noise ratio at the farther-away sensors, which could result in marker positions that cannot be resolved accurately and unambiguously. In these cases, it may be preferred to change modes to a simpler 1D gradient-localization mode, which can be achieved with just one magnetic sensor. The localization mode could be set up to be changed via user input, or it could be done automatically. The processor may be configured with a first mode in which the disposition of the magnetic marker is determined in five degrees of freedom and a second mode wherein the disposition of the magnetic marker is determined using a subset of the available magnetic sensors—for example, a single magnetic sensor.

The probe may include a user interface in electronic communication with the processor. The processor is further configured to provide a signal of the determined disposition of the magnetic marker to the user interface. The user interface may be, for example, a display, such as a computer monitor, or smartphone screen, a tablet screen, etc. In such embodiments, the user interface may display a graphical representation of the marker location according to the signal received form the processor. In some embodiments, the user interface is an audio source. The audio source may be configured to audibly represent the determined disposition of the magnetic marker according to the signal provided from the processor. The user interface may have more than one modality (e.g., both a display and an audio source). In some embodiments, the processor is further configured to provide an indicator signal when magnetic field gradients which are not consistent with the magnetic marker are detected. For example, the processor may signal a display to display a message symbol, or any other indicator or indicia (e.g., color-coding, etc.) to inform a user that a detected signal may not be a magnetic marker.

FIG. 2 depicts another embodiment of a probe 210 having a substrate 212 with a first side 214 and a second side 216. The probe 210 has a first magnetic sensor 226 disposed on the first side of the substrate. The probe 210 has a second magnetic sensor 220 disposed on the first side of the substrate. The probe 210 has a third magnetic sensor 224 disposed on the second side of the substrate. The probe 210 has a fourth magnetic sensor 222 and a fifth magnetic sensor 225, each disposed on the first side of the substrate. The probe 210 has a sixth magnetic sensor 223, a seventh magnetic sensor 227, and an eighth magnetic sensor 228, each disposed on the second side of the substrate. A processor 240 is in electronic communication with each of the first, second, third, fourth, fifth, sixth, seventh, and eighth magnetic sensors.

FIG. 3 depicts another embodiment of a probe 310 having a substrate 312 with a first side 314 and a second side 316. The probe 310 has a first magnetic sensor 326 disposed on the first side of the substrate. The probe 310 has a second magnetic sensor 320 disposed on the first side of the substrate. The probe 310 has a third magnetic sensor 325 disposed on the second side of the substrate. The probe 310 has a fourth magnetic sensor 322, a fifth magnetic sensor 324, and a sixth magnetic sensor 328, each disposed on the first side of the substrate. The probe 310 has a seventh magnetic sensor 321, an eighth magnetic sensor 323, and a ninth magnetic sensor 329, each disposed on the second side of the substrate. A processor 340 is in electronic communication with each of the first, second, third, fourth, fifth, sixth, seventh, eighth, and ninth magnetic sensors.

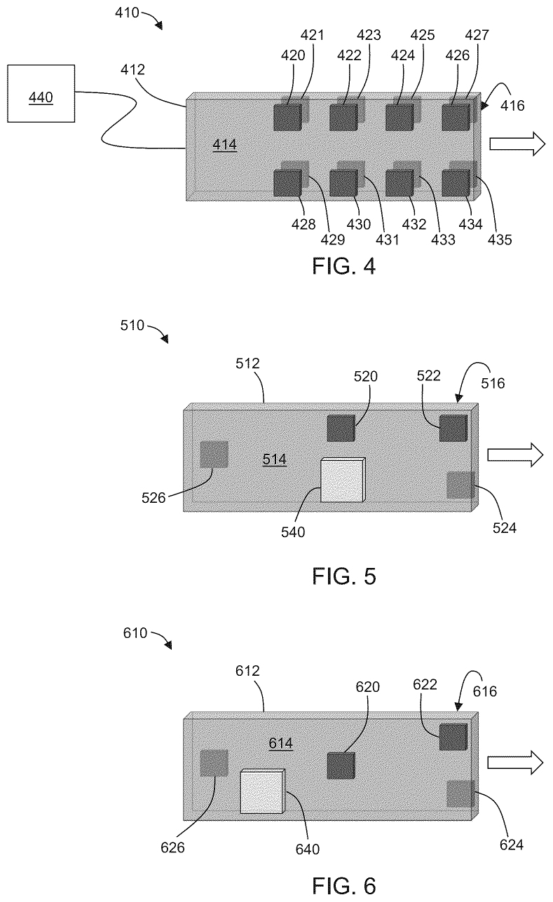

FIG. 4 depicts another embodiment of a probe 410 having a substrate 412 with a first side 414 and a second side 416. The probe 410 has a first magnetic sensor 420 disposed on the first side of the substrate. The probe 410 has a second magnetic sensor 422 disposed on the first side of the substrate. The probe 410 has a third magnetic sensor 421 disposed on the second side of the substrate. The probe 410 has a fourth magnetic sensor 424, a fifth magnetic sensor 426, a sixth magnetic sensor 428, a seventh magnetic sensor 430, an eighth magnetic sensor 432, and a ninth magnetic sensor 434, each disposed on the first side of the substrate. The probe 410 has a tenth magnetic sensor 423, an eleventh magnetic sensor 425, a twelfth magnetic sensor 427, a thirteenth magnetic sensor 429, a fourteenth magnetic sensor 431, a fifteenth magnetic sensor 433, and a sixteenth magnetic sensor 435, each disposed on the second side of the substrate. A processor 440 is in electronic communication with each of the first, second, third, fourth, fifth, sixth, seventh, eighth, ninth, tenth, eleventh, twelfth, thirteenth, fourteenth, fifteenth, and sixteenth magnetic sensors.

FIG. 5 depicts another embodiment of a probe 510 having a substrate 512 with a first side 514 and a second side 516. The probe 510 has a first magnetic sensor 520 disposed on the first side of the substrate. The probe 510 has a second magnetic sensor 522 disposed on the first side of the substrate. The probe 510 has a third magnetic sensor 524 disposed on the second side of the substrate. The probe 510 has a fourth magnetic sensor 526 disposed on the second side of the substrate. A processor 540 is in electronic communication with each of the first, second, third, and fourth magnetic sensors.

FIG. 6 depicts another embodiment of a probe 610 having a substrate 612 with a first side 614 and a second side 616. The probe 510 has a first magnetic sensor 620 disposed on the first side of the substrate. The probe 610 has a second magnetic sensor 622 disposed on the first side of the substrate. The probe 610 has a third magnetic sensor 624 disposed on the second side of the substrate. The probe 610 has a fourth magnetic sensor 626 disposed on the first side of the substrate. In the probe 610 embodiment depicted in FIG. 6, the first magnetic sensor 620 is aligned with the fourth magnetic sensor 626 along the longitudinal axis and spaced apart from the second magnetic sensor 622 along the transverse axis (compare with probe 510 of FIG. 5 where the first magnetic sensor 520 is aligned with the second magnetic sensor 522 along the longitudinal axis and spaced apart from the fourth magnetic sensor 526 along the transverse axis). A processor 640 is in electronic communication with each of the first, second, third, and fourth magnetic sensors.

Although the present disclosure has been described with respect to one or more particular embodiments, it will be understood that other embodiments of the present disclosure may be made without departing from the spirit and scope of the present disclosure.

1. A probe for determining a position and pose of an anisotropic magnetic marker having a known size, shape, and magnetization, the probe comprising:
a substrate having a first side, a second side, a longitudinal axis, and a transverse axis;
a first magnetic sensor disposed on the first side of the substrate;
a second magnetic sensor disposed on the first side of the substrate and spaced apart from the first magnetic sensor along the longitudinal axis of the substrate and spaced apart from the first magnetic sensor along the transverse axis of the substrate;
a third magnetic sensor disposed on the second side of the substrate;
wherein each of the first magnetic sensor, the second magnetic sensor, and the third magnetic sensor is a multidimensional magnetic sensor,
a processor in electronic communication with the first magnetic sensor, the second magnetic sensor, and the third magnetic sensor, wherein the processor is configured to determine a disposition of the magnetic marker in five degrees of freedom based on the known size, shape, and magnetization and signals received from each of the first, second, and third magnetic sensors.

2. The probe of claim 1, wherein the spacing between the first and second magnetic sensors is greater along the longitudinal axis than the spacing between the first and second magnetic sensors along the transverse axis.

3. The probe of claim 2, wherein at least one of the first magnetic sensor, the second magnetic sensor, and the third magnetic sensor is oriented such that no measurement axis is parallel with the longitudinal axis of the substrate.

4. The probe of claim 2, wherein at least one of the first magnetic sensor, the second magnetic sensor, and the third magnetic sensor has a different orientation from the other magnetic sensors.

5. The probe of claim 1, wherein the third magnetic sensor is spaced apart from the first magnetic sensor along the longitudinal axis.

6. The probe of claim 5, wherein the third magnetic sensor is spaced apart from the first magnetic sensor along the transverse axis.

7. The probe of claim 5, wherein the third magnetic sensor is spaced apart from the second magnetic sensor along the longitudinal axis and/or the transverse axis.

8. The probe of claim 1, further comprising a fourth magnetic sensor on the first side of the substrate.

9. The probe of claim 1, further comprising a fourth magnetic sensor on the second side of the substrate.

10. The probe of claim 8, wherein the fourth magnetic sensor is spaced apart from the third magnetic sensor along the longitudinal axis and/or the transverse axis.

11. The probe of claim 1, wherein a maximum total spacing between the first magnetic sensor, the second magnetic sensor, and the third magnetic sensor along the transverse axis is less than or equal to 12 mm.

12. The probe of claim 11, wherein a maximum total spacing between the first magnetic sensor, the second magnetic sensor, and the third magnetic sensor along the longitudinal axis is between 1.25 and 10 times the maximum total spacing along the longitudinal axis.

13. The probe of claim 1, wherein the substrate has a thickness of between 0.5 mm and 10 mm.

14. The probe of claim 1, further comprising a user interface in electronic communication with the processor, and wherein the processor is further configured to provide a signal of the determined disposition of the magnetic marker to the user interface.

15. The probe of claim 14, wherein the user interface is a monitor configured to display the determined disposition of the magnetic marker according to the signal provided from the processor.

16. The probe of claim 14, wherein the user interface is an audio source configured to audibly represent the determined disposition of the magnetic marker according to the signal provided from the processor.

17. The probe of claim 1, wherein the processor has a first mode in which the disposition of the magnetic marker is determined in five degrees of freedom and a second mode wherein the disposition of the magnetic marker is determined using one of the first magnetic sensor, the second magnetic sensor, or the third magnetic sensor.

18. The probe of claim 1, wherein the processor is configured to determine more than one disposition of the magnetic marker over time.

19. The probe of claim 1, wherein the processor is configured to periodically determine the disposition of the magnetic marker at a sampling frequency.

20. The probe of claim 1, wherein the substrate is contained within a probe housing.

21. The probe of claim 20, wherein the processor is located outside the probe housing.

22. The probe of claim 1, wherein the processor is further configured to provide an indicator signal when magnetic field gradients which are not consistent with the magnetic marker are detected.

23. The probe of claim 1, wherein the processor is further configured to disregard magnetic field gradients which are not consistent with the magnetic marker.

24. The probe of claim 1, wherein one of the first magnetic sensor, the second magnetic sensor, or the third magnetic sensor is spaced apart from the other magnetic sensors along the longitudinal axis and configured to measure a background magnetic field.

25. The probe of claim 1, further comprising a background magnetic sensor spaced apart from the first magnetic sensor, the second magnetic sensor, and the third magnetic sensor, along the longitudinal axis, and configured to measure a background magnetic field.
